(19) United States
(12) Patent Application Publication
(10) Pub. No.: US 2004/0083417 A1
(43) Pub. Date: Apr. 29, 2004

(54) Multimedia transmission using variable error coding rate based on data importance

(76) Inventors: Richard D. Lane, San Diego, CA (US); Maksim Krasnyanskiy, San Diego, CA (US); Mark Charlebois, San Diego, CA (US); Ricardo Jorge Lopez, San Marcos, CA (US); William R. Gardner, San Diego, CA (US)

Correspondence Address: Qualcomm Incorporated, Patents Department, 5775 Morehouse Drive, San Diego, CA, 92121-1714, US

(21) Appl. No.: 10/283,904

(22) Filed: Oct. 29, 2002

(51) Int. Cl. H03M 13/00

(52) U.S. Cl. 714/758

(57) ABSTRACT

A broadcast multimedia data stream is partitioned into two or more parts based on importance, e.g., a first part might represent more significant bits in groups of bits representing pixel colors in a video frame, while a second part might represent the less significant bits in the groups. The more important part of the stream is error correction coded at a lower rate or using a more powerful coding technique (i.e., with more error correction coding) than is the less important part of the stream.

### FIELD OF THE INVENTION

The present invention relates generally to multimedia broadcast transmission.

### BACKGROUND

Multimedia such as video and audio can be transmitted over a number of paths, including cable, the Internet, and broadcast. For instance, satellite or terrestrial broadcast stations can be used to transmit multimedia to mobile computing devices such as mobile telephones.

Typically, multimedia data is voluminous, which means that significant transmission path bandwidth, unfortunately a finite resource, must be used. This is particularly the case for high fidelity multimedia, e.g., high resolution video. That is, the higher the quality of service being provided, the more bandwidth must be used.

As recognized by the present invention, some portions of a multimedia stream are more important than other portions. For example, a digitized, uncompressed video stream can be represented by a sequence of pixels. Each pixel may be represented by a 24 bit integer number. These 24 bits maybe partitioned into 8 bits representing the redness, 8 bits of greenness, and 8 bits of blueness. When combined in an appropriate fashion these values define the color of the pixel.

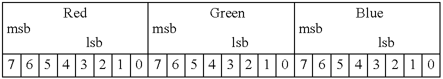

The first bit of each 8-bit group (bit 7 of each color) is generally more significant (msb) than the last bit (lsb or bit 0 of each color). In other words, while the use of 8 bits allows for the indication of 256 shades of a color, the left-most bits (bit 7 of each color), which indicate whether at least some significant amount (usually half or a value of 128) of the color (red, green, or blue) is or is not present in the pixel, are more important than the right-most bits (usually a single bit or a value of 1), which indicate subtleties in the pixel's color that, while improving the quality of the image when present, are not necessary to providing at least some recognizable image, in contrast to the more important bits. Stated differently, the first bit contributes more to the overall picture quality than the following bits, which incrementally improve the quality afforded by the first bit.

The present invention further recognizes that the principle of “importance” extends to other encodings/compressed data as well. More generally, it applies to any data in multimedia streams that represent magnitude. It can also apply to the relative importance of different types of multimedia data. Some data may be more sensitive to errors while other data might be more sensitive to delays.

For digitized video, in addition to the pixel data discussed above such magnitude-indicating data in compressed streams can include header information, motion vectors, and DCT coefficients. In digitized audio, magnitude-indicating data in uncompressed streams can include MdBs of PCM data, or in compressed streams can include spectral envelope information and bandpass scaled signals. Also, some frequencies of an audible sound represented in a stream might be more important than other frequencies that make up the sound.

Having made the above critical observation, the present invention further understands that it is common to minimize the effect of errors in the transmission of bits in a digitized multimedia stream by error coding techniques. In broadcast applications, the present invention recognizes the desirability of providing a graceful degradation of reception quality to users at the edge of the broadcast area. Instead of transmitting a single instance of a bit, more than one instance of the bit can be transmitted, with the receiver averaging bits in a group to decode the original value. In this way, even if one of the copies of the encoded bit is corrupted, the “correct” value will be obtained after averaging. As a simple example, instead of transmitting a single bit representing +1 and risking the possibility that the bit will be corrupted and hence lost in transmission, the bit can be encoded into three instances (+1, +1, +1) so that the loss of any one encoded bit in the group will not result in the loss of data at the receiver, because the remaining bits will decode to the correct value. In the above example, the received stream of bits was (+1, 0, +1), two of the three bits were +1 and therefore the receiver would interpret the sequence (+1, 0, +1) as a +1.

In the above example, the coding rate, which is the ratio of input bits to output bits, is ⅓ (or 1 input bit to 3 output bits). It is to be understood that more input bits than one can be used and other coding rates can be used in accordance with error correction coding principles. In any case, it is to be appreciated that the lower the coding rate, the higher the bit repetition and, hence, the higher the bandwidth requirement. That is, a trade-off exists between conserving bandwidth and maximizing error correction. More sophisticated schemes can be used if desired.

With the above considerations in mind, the present invention has been provided.

### SUMMARY OF THE INVENTION

The invention establishes different error coding rates for different parts of a multimedia stream, based on relative “importance” or “sensitivity to errors” or “desire for data correctness” or “sensitivity to delay” of the different parts. Specifically, more important parts are coded at less powerful error codings (and thus have more robust error correction coding) than less important parts. A “more powerful error coding” can mean the same type of coding but at a lower rate than used for the less important part, e.g., a rate ⅓ block coding is more powerful than a rate ½ block coding. Or, “more powerful error coding” can mean using a more powerful error coding technique compared to the technique used for the less important part, e.g., more important parts can be encoded using convoluitonal coding and less important parts can be encoded using block coding, or more important parts can be encoded using turbo coding and less important parts can be encoded using convoluitonal coding. For purposes of this document, “sensitivity to errors” is used specifically and as a general term for all four reasons for using different error codings.

Accordingly, a method for multimedia data transmission includes establishing at least first and second error codings for at least first and second parts, respectively, of a broadcast multimedia data stream. The first and second codings are different from each other. Specifically, a more important part of the stream is coded at a more powerful coding than a less important part, which might not be error correction encoded at all (i.e., which might be coded at a coding rate of unity). The stream represents a single program, and it is partitioned based on the relative importance of the parts.

The multimedia data stream can be broadcast using wireless transmission principles or it can be transmitted over cable, including over the Internet. Also, the multimedia stream can be partitioned into more than two parts, with each part having its own coding.

As set forth in greater detail below, the first and second parts can be first and second groups of bits representing a single magnitude. The magnitude can be a magnitude of a single pixel, and more specifically the magnitude can be a magnitude of a single color of a single pixel. Or, the first and second parts can be first and second groups of bits in a header of a video stream, or first and second groups of bits in a motion vector of a video stream, or first and second groups of bits in a DCT coefficient in a video stream, or first and second groups of bits representing spectral envelope information in an audio stream, or first and second groups of bits representing bandpass scaled signals in an audio stream, or first and second parts of graphics parameters, or first or second parts of spectral transform coefficients, or first and second groups of pixels in a frame, or first or second groups of frames, or first and second groups of bits representing spectral envelope information in an audio stream, or first and second groups of bits representing bandpass scaled signals in an audio stream, or other appropriate bits. In any case, the first group of bits may be more significant than the second group of bits. The first and second parts can also represent data or other multimedia information of varying importance, sensitivity to error or sensitivity to delay.

In another aspect, a system is disclosed for broadcasting a multimedia data stream that represents a single multimedia program. The system includes a data divider that partitions the stream into at least first and second parts. A first error correction coder applies a first error encoding to the first part, while a second error correction coder applies a second error encoding to the second part. The stream is transmitted by a transmitter.

In yet another aspect, a system for receiving a multimedia data stream includes a data divider partitioning the stream into at least first and second parts, and a first error correction decoder applying a first error decoding to the first part. Also, a second error correction decoder applies a second error decoding to the second part. A data combiner

is provided for combining the parts for playing the stream.

In further non-limiting embodiments, the multimedia data can be subdivided into numerically equivalent parts. One non-limiting example would be to select every other pixel for one part and the alternate pixels for the second part. The first part could be sent with a greater or error coding gain than the second part. Another non-limiting case would be to select the odd frames for part one and the even frames for part two. Again, the first part could be sent with a greater gain or error coding than the second part. The relative importance of the parts may be viewed as numerically equal parts but may still be assigned different gains or error codings. The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a simplified block diagram of one exemplary multimedia stream transmitter;

FIG. 2 is a simplified block diagram of one exemplary multimedia stream receiver; and

FIG. 3 is a flow chart of the present logic.

### DETAILED DESCRIPTION OF THE PREFERRED EMBODIMENT

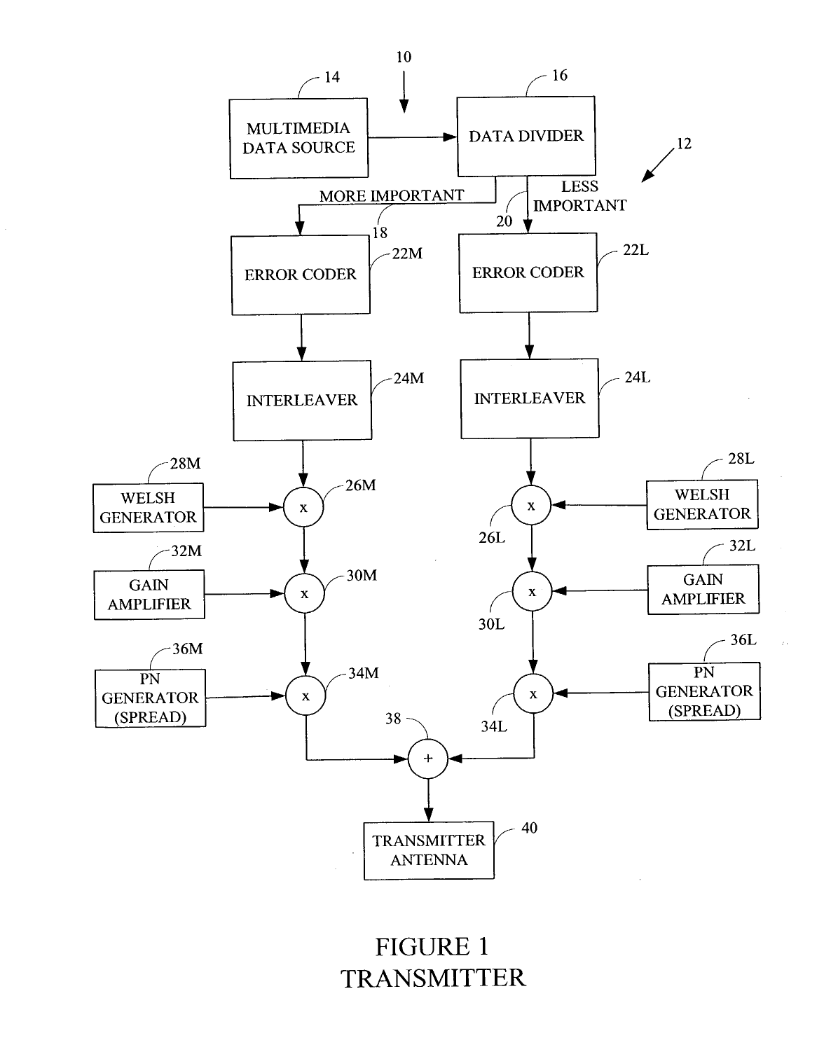

The non-limiting preferred embodiment shown in FIG. 1 illustrates multimedia broadcast using wireless means, and more particularly using code division multiple access (CDMA) principles. It is to be understood that the present principles apply to other forms of wireless communication such as GSM, TDMA, wideband CDMA, EDGE, Digital TV, conventional TV, radio, iBiquity (IBOC) digital radio, XM, etc. as well as broadcast transmission of multimedia over cable systems, the Internet, etc. By “broadcast” is meant transmisison to plural receivers in the area covered by the broadcast, as opposed to, e.g., point-to-point transmission between a wireless communication infrastructure and a wireless telephone. It is to be further understood that while for simplicity the disclosure below assumes that a multimedia stream has only two data partitions and, hence, uses only two code channels, additional partitions based on relative importance can be used.

As used herein in the singular, “multimedia stream” means a single stream representing a single program, e.g., a single music piece or a single television show or movie. The term “Multimedia Stream” defines a group of related information, the distinct components of which are to be referred to in this document as “Multimedia Sub-streams” or just “Sub-streams”, which when combined, provide a complete composite experience for the users or receivers of that multimedia stream. An example would be music data accompanied by a picture and perhaps some text. The music, picture and text data could be coded into three sub-streams. Indeed, different parts of closed-captioning text maybe error coded differently from each other. The digitized and compressed audio could be coded and transmitted separately from the picture data, which in turn could be separate from the text data. Still further, graphics overlays, video add-ons, and audio add-ons that are associated with a video stream could be coded at a different (e.g., higher) coding rate than the underlying video stream. In general, the present invention aplies to data having parts of relative importances, e.g., full text documents might be of less importance and thus error coded at a higher rate than an accompanying schematic diagram. However, the present invention may be applied to different parts of equal importance.

Focussing back on broadcast multimedia, a receiver could gather the various “Multimedia Sub-streams” and present them in a manner appropriate for the receiving device or player. For clarity, when combined, the three sub-streams comprise a “Multimedia Stream”. “Multimedia stream” when used in the singular accordingly does not encompass commonly broadcast or commonly carried multiple distinct program streams.

As shown in FIG. 1, a system 10 can include at least one transmitter 12 that receives multimedia programs from a source 14 of multimedia data. As also shown in FIG. 1, a multimedia data stream is input to a data divider 16, which partitions at least portions of the stream into a more important part 18 and a less important part 20, although the stream can be partitioned into more parts than two. As discussed in the example below, the partitioning can be done in accordance with a predetermined importance of the parts. The two partitions are then processed in respective channels. First, each part 18, 20 is processed by a respective error coder 22M, 22L for error coding. While any appropriate error coding can be used, in one non-limiting exemplary embodiment the coding may include replicating or repeating each bit N times, wherein N>1, such that each part 18, 20 is coded at a respective coding rate. The “coding rate” refers to the ratio of original source bits to the number of bits after coding has been applied.

R=B/A

Where R refers to the coding Rate, B is the number of bits before coding and A is the number of bits after coding. The greater the repetition of bits the stronger the code and the more resistant to channel errors.

The coding rate used for the less important part 20 can be greater than the coding rate used for the more important part 18. The coding rate for the less important part can be unity, i.e., the less important part might not be error coded at all. When more than two partitions (divided by importance) are used, the coding rates of the three or more parts can be successively greater, from more important to less important. That is, more important bits undergo more error coding-related replication than less important bits. As mentioned above, however, instead of using the same type of coding for each part and varying the rates, stronger and weaker error coding schemes can be respectively used for the more important and less important parts. It is conceivable that a multimedia stream could have sub-streams which are of equal importance. In this instance those sub-streams could be coded at the same coding rate or at different coding rates.

With particular regard to the exemplary non-limiting wireless multimedia transmission set forth herein, after error coding the parts 18, 20 can be processed by respective interleavers 24M, 24L in accordance with principles known in the art. The symbols in the error correction encoded symbol stream for each channel can be converted to real integers (e.g., “0” to a plus one and “1” to a minus one) and then digitally multiplied at 26M, 26L by an assigned Walsh function or sequence from a respective Walsh generator 28M, 28L. Then, the parts 18, 20 can be multiplied at 30M, 30L by respective gain factors G₁, G₂ provided from gain amplifiers 32M, 32L.

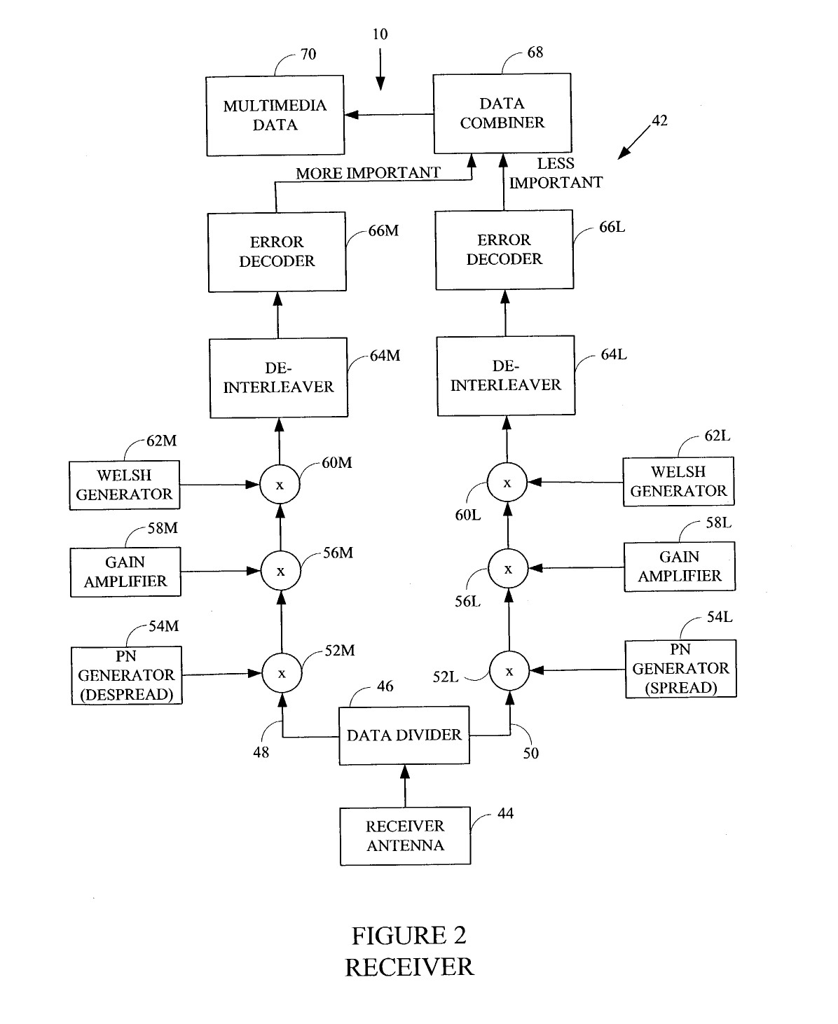

Continuing, the parts 18, 20 may next be digitally multiplied at 34M, 34L by or combined with an outer pseudorandom (PN) code from a respective PN generator 36M, 36L after converting it to a sequence of the real field. The resulting spread symbol streams for each signal are then combined together at a summer 38 to form a composite waveform for transmission using a transmitter antenna 40. It is to be understood that the summer 38 can be interposed at other locations in the transmitter downstream of the coders 22M, 22L to combine the two channels into one when only different error correction coding is used. There could be multiple transmitters and even multiple physical layers used to transmit the different sub-streams but for clarity of disclosure a single transmitter is shown. In relevant part and for simplicity, a receiver 42 of the exemplary non-limiting wireless system 10 is shown in FIG. 2 to be the inverse of the transmitter 12. Specifically, the receiver 42 can include a receiver antenna 44 with associated signal processing circuitry known in the art that produces the digitized multimedia stream that had been transmitted. The stream is sent to a data divider 46, which partitions the stream into a more important part 48 and a less important part 50 using the same criteria that was used by the data divider 16 of the transmitter 12.

The parts 48, 50 are de-spread at 52M, 52L using respective PN sequences from PN generators 54M, 54L. The PN sequences used for de-spreading are the same as those used for spreading in the transmitter 12. If desired, the gains of the parts 48, 50 can be adjusted at 56M, 56L using signals from respective gain amplifiers 58M, 58L.

Next, the parts are Walsh-demodulated at 60M, 60L using signals from respective Walsh generators 62M, 62L in accordance with principles known in the wireless communication art. The parts 48, 50 are next de-interleaved at respective de-interleavers 80M, 80L.

In accordance with the present invention, respective error decoders 66M, 66L decode the parts 48, 50 using the inverse of the error correction codings that were applied by the transmitter 12 to the parts 18, 20. Accordingly, the error decoder 66M uses a coding to decode the more important part 48 that corresponds to the coding used by the encoder 22M and the decoder 66L for the less important part 50 uses a coding that corresponds to the coding used by the encoder 22L. As discussed above, when more than two partitions are used, the codings of the three or more parts are successively stronger, from more important to less important. The parts 48, 50 are then combined at a combiner 68 (such as a summer or other transform) to produce the original multimedia data stream, indicated at block 70 of FIG. 2. Thus, when the first and second parts are first and second groups of pixels in a video frame and are combined together, they form an image resolution greater than either the first or second part alone.

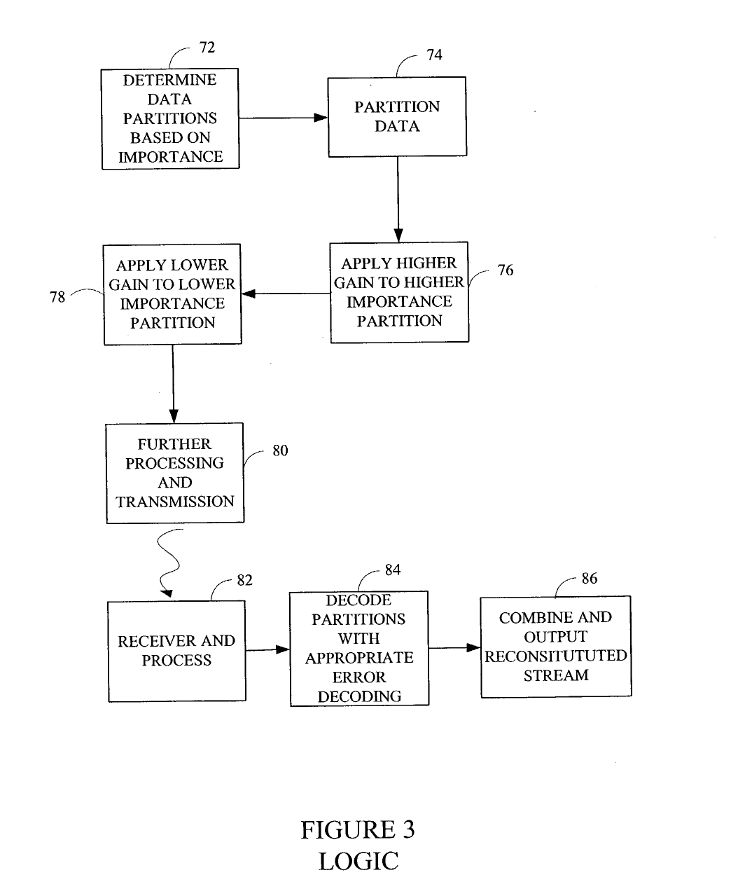

FIG. 3 illustrates the logic of the present invention. Commencing at block 72, it is determined how the stream is to be partitioned. As discussed above, two or more partitions can be used, based on the relative importance of the parts of the stream or other useful partitions of the multimedia stream. For instance, it might be decided that each 8-bit group representing a pixel color for a single frame of a video stream will be partitioned into two parts, with the more important part being the left-most (most significant) 6 bits and the less important part being the remaining two bits, as shown below:

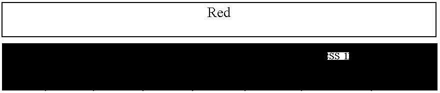

Or, the group can divided evenly, with the four left-most (most significant) bits being in the more important part and the four less significant bits being in the less important part thusly:

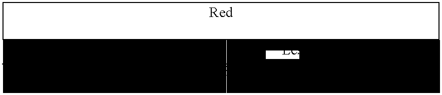

Other bit divisions can be used. Yet again, the 8-bit group can be partitioned into three or more groups. Still further, other data in a compressed stream, particularly magnitude-indicating data such as certain header data, motion vectors, and DCT coefficients for video data and spectral envelope information and bandpass scaled signals for audio data, can be partitioned into more important and less important parts. For data, pictures, text, graphics and other types of multimedia streams or sub-streams, there are many other useful partitioning schemes. For instance, the present invention may be applied to magnitude measures in broadcast graphics including object size, warping, translation, point of view, lighting, rotation orientation, perspective, etc. as well as to different graphics objects to which the user may attach different “importances”. Moreover, in addition to audio, video, text, and graphics, the invention may apply to more and less important parts of general data, picture control information encryption keys system control decoding parameters, basis function sets, ordering information related to HTML, URLs, etc. Still further examples of parts include first and second groups of Wavelet coefficients in at least one group of Wavelet coefficients in a video stream, or first and second groups of spectral transform coefficients in at least one group of spectral transform coefficients in a video stream, or first and second parts of a video frame in at least one group of Graphics parameters in a graphics stream, or first and second groups of Graphics parameters in at least one group of Graphics parameters in a graphics stream. In any case, the partitioning scheme at block 72 is used by the data dividers 16, 46 of the transmitter and receiver to partition the stream. If desired, block 70 can be undertaken once and provided to the receiver 42 prior to multimedia stream broadcast, or it can be undertaken dynamically, with the particular partitioning scheme being broadcast to the receiver 42 at broadcast time. Alternatively, a receiver could have partitioning information stored in memory or transmitted by another physical layer.

Moving to block 72, the transmitter 12 partitions the stream in accordance with the partitioning scheme as discussed above. At blocks 76 and 78, the error correction coders 22M, 22L (FIG. 1) apply their respective codings to their respective parts of the stream. Specifically, the more important parts are encoded at lower rates (or using more powerful error coding) at block 76 than the less important parts that are encoded at block 78. While blocks 76 and 78 are shown in series for convenience of disclosure, the coding of the different parts can be done in parallel as described in reference to FIG. 1. Proceeding to block 80, the parts of the stream undergo the subsequent processing described above, and then are transmitted.

Block 82 represents the reception and pre-decoding processing undertaken by the receiver 42 as discussed above with respect to FIG. 2. At block 84, the decoders 66M, 66L of the receiver 42 decode their respective parts using the codings that had been applied by the transmitter 12. At block 86, the parts are combined to reconstitute the multimedia stream.

While the particular MULITMEDIA TRANSMISSION USING VARIABLE ERROR CODING RATE BASED ON DATA IMPORTANCE as herein shown and described in detail is fully capable of attaining the above-described objects of the invention, it is to be understood that it is the presently preferred embodiment of the present invention and is thus representative of the subject matter which is broadly contemplated by the present invention, that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more”. All structural and functional equivalents to the elements of the above-described preferred embodiment that are known or later come to be known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. '112, sixth paragraph, unless the element is expressly recited using the phrase “means for” or, in the case of a method claim, the element is recited as a “step” instead of an “act”.

What is claimed is:

1. A method for multimedia data broadcast, comprising:
establishing at least first and second error codings for at least first and second parts, respectively, of a multimedia stream representing a single program, based on relative importance of the parts, the first and second codings being different from each other; and
broadcasting the multimedia data.

2. The method of claim 1, wherein a more important part is coded at a lower rate than a less important part.

3. The method of claim 2, wherein the less important part is coded at a coding rate of unity.

4. The method of claim 1, wherein the data is broadcast wirelessly.

5. The method of claim 1, wherein the data is broadcast over cable.

6. The method of claim 1, wherein at least first, second, and third error codings are used for respective first, second, and third parts of the multimedia stream.

7. The method of claim 1, wherein the first and second parts are first and second groups of bits representing a single magnitude.

8. The method of claim 7, wherein the magnitude is a magnitude of a single pixel.

9. The method of claim 8, wherein the magnitude is a magnitude of a single color of a single pixel.

10. The method of claim 7, wherein each group of bits contains at least one bit.

11. The method of claim 7, wherein the first and second parts are first and second groups of bits in a header of a video stream.

12. The method of claim 7, wherein the first and second parts are first and second groups of bits in a motion vector of a video stream.

13. The method of claim 7, wherein the first and second parts are first and second groups of bits in at least one DCT coefficient in a video stream.

14. The method of claim 7, wherein the first and second parts are first and second groups of DCT coefficients in at least one group of DCT coefficients in a video stream.

15. The method of claim 7, wherein the first and second parts are first and second groups of bits representing spectral envelope information in an audio stream.

16. The method of claim 7, wherein the first and second parts are first and second groups of bits representing bandpass scaled signals in an audio stream.

17. The method of claim 8, wherein the first group of bits is more significant than the second group of bits.

18. The method of claim 17, wherein the first group of bits is to the left of the second group of bits when the bits are represented in their intended sequence.

19. The method of claim 1, wherein the first and second parts are first and second groups of Wavelet coefficients in at least one group of Wavelet coefficients in a video stream.

20. The method of claim 1, wherein the first and second parts are first and second groups of spectral transform coefficients in at least one group of spectral transform coefficients in a video stream.

21. The method of claim 1, wherein the first and second parts are first and second parts of a video frame in at least one group of Graphics parameters in a graphics stream.

22. The method of claim 1, wherein the first and second parts are first and second groups of Graphics parameters in at least one group of Graphics parameters in a graphics stream.

23. The method of claim 1, wherein the first and second parts are first and second groups of pixels in a video frame.

24. The method of claim 23, wherein the first and second parts when combined together at the receiver form an image resolution greater than either the first or second part alone.

25. The method of claim 1, wherein the first and second parts are first and second groups of frames in a video stream.

26. The method of claim 25, wherein the first and second parts when combined together at the receiver form a temporal resolution greater than either the first or second part alone.

27. A system for broadcasting at least one multimedia data stream representing a single multimedia program, comprising:
a data divider partitioning the stream into at least first and second parts;
a first error correction coder applying a first error encoding to the first part;
a second error correction coder applying a second error encoding to the second part; and
a broadcast transmitter for transmitting the data stream.

28. The system of claim 27, wherein the transmitter is a wireless transmitter.

29. The system of claim 28, wherein the transmitter transmits the stream using CDMA principles.

30. The system of claim 28, wherein the transmitter transmits the stream using OFDM principles.

31. The system of claim 27, wherein the transmitter transmits the stream over a cable.

32. The system of claim 27, wherein the first part is a more important part and the second part is a less important part.

33. The system of claim 27, wherein the first part is a more sensitive to errors and the second part is a less sensitive to errors.

34. The system of claim 27, wherein the first part is a more important data type and the second part is a less data type.

35. The system of claim 27, wherein the first part is a more important sub-stream type and the second part is a less sub-stream type.

36. The system of claim 27, wherein the first part is a more sensitive to delay and the second part is a less sensitive to delay.

37. The system of claim 27, wherein at least one bit in the first part is more significant than any bit in the second part.

38. The system of claim 27, wherein the first error correction coder codes the first part at a coding rate less than a coding rate applied to the second part.

39. The system of claim 27, wherein the data divider partitions the stream into at least three parts.

40. The system of claim 39, wherein at least first, second, and third error coding rates are used for respective first, second, and third parts of the multimedia data stream.

41. The system of claim 27, wherein the first and second parts are first and second groups of bits representing a single magnitude.

42. The system of claim 41, wherein the magnitude is a magnitude of a single pixel.

43. The system of claim 42, wherein the magnitude is a magnitude of a single color of a single pixel.

44. The system of claim 41, wherein each group of bits contains at least one bit.

45. The system of claim 41, wherein the first and second parts are first and second groups of bits in a header of a video stream.

46. The system of claim 41, wherein the first and second parts are first and second groups of bits in a motion vector of a video stream.

47. The system of claim 41, wherein the first and second parts are first and second groups of bits in at least one DCT coefficient in a video stream.

48. The system of claim 27, wherein the first and second parts are first and second groups of DCT coefficients in at least one group of DCT coefficients in a video stream.

49. The system of claim 27, wherein the first and second parts are first and second groups of bits representing spectral envelope information in an audio stream.

50. The system of claim 27, wherein the first and second parts are first and second groups of bits representing bandpass scaled signals in an audio stream.

51. The system of claim 27, wherein the first and second parts are first and second groups of Wavelet coefficients in at least one group of Wavelet coefficients in a video stream.

52. The system of claim 27, wherein the first and second parts are first and second groups of spectral transform coefficients in at least one group of spectral transform coefficients in a video stream.

53. The system of claim 27, wherein the first and second parts are first and second parts of a video frame in at least one group of Graphics parameters in a graphics stream.

54. The system of claim 27, wherein the first and second parts are first and second groups of Graphics parameters in at least one group of Graphics parameters in a graphics stream.

55. The system of claim 27, wherein the first and second parts are first and second groups of pixels in a video frame.

56. The system of claim 27, wherein the first and second parts when combined together at the receiver form an image resolution greater than either the first or second part alone.

57. The system of claim 27, wherein the first and second parts are first and second groups of frames in a video stream.

58. The system of claim 57, wherein the first and second parts when combined together at the receiver form a temporal resolution greater than either the first or second part alone.

59. A system for receiving at least one broadcast multimedia data stream representing a single multimedia program, comprising:
a data divider partitioning the stream into at least first and second parts;
a first error correction decoder applying a first error decoding to the first part;
a second error correction decoder applying a second error decoding to the second part; and
a data combiner combining the parts for playing the stream.

60. The system of claim 59, wherein the receiver is a wireless receiver.

61. The system of claim 60, wherein the receiver receives the stream using CDMA principles.

62. The system of claim 60, wherein the receiver receives the stream using OFDM principles.

63. The system of claim 59, wherein the receiver receives the stream over a cable.

64. The system of claim 59, wherein the first part is a more important part and the second part is a less important part.

65. The system of claim 59, wherein the first part is a more sensitive to errors and the second part is a less sensitive to errors.

66. The system of claim 59, wherein the first part is a more important data type and the second part is a less data type.

67. The system of claim 59, wherein the first part is a more important sub-stream type and the second part is a less sub-stream type.

68. The system of claim 59, wherein the first part is a more sensitive to delay and the second part is a less sensitive to delay.

69. The system of claim 59, wherein at least one bit in the first part is more significant than any bit in the second part.

70. The system of claim 59, wherein the first error correction decoder decodes the first part at a coding rate less than a coding rate applied to the second part.

71. The system of claim 59, wherein the first and second parts are first and second groups of bits representing a single magnitude.

72. The system of claim 71, wherein the magnitude is a magnitude of a single pixel.

73. The system of claim 72, wherein the magnitude is a magnitude of a single color of a single pixel.

74. The system of claim 71, wherein each group of bits contains at least one bit.

75. The system of claim 59, wherein the first and second parts are first and second groups of bits in a header of a video stream.

76. The system of claim 59, wherein the first and second parts are first and second groups of bits in a motion vector of a video stream.

77. The system of claim 59, wherein the first and second parts are first and second groups of bits in at least one DCT coefficient in a video stream.

78. The system of claim 59, wherein the first and second parts are first and second groups of bits representing spectral envelope information in an audio stream.

79. The system of claim 59, wherein the first and second parts are first and second groups of bits representing bandpass scaled signals in an audio stream.

80. A communication system for multimedia data broadcasting, comprising:
means for applying at least first and second error codings to at least first and second parts, respectively, of a multimedia data stream representing a single program, based on relative importance of the parts, the first and second codings being different from each other.

81. The system of claim 80, wherein the means for applying encodes a more important part at a lower rate than a less important part.

82. The system of claim 80, wherein the means for applying includes at least a first error correction coder applying a first coding rate to the first part and a second error correction coder applying a second coding rate to the second part.

83. The system of claim 80, wherein the data is transmitted wirelessly.

84. The system of claim 80, wherein the data is transmitted over cable.

85. The system of claim 80, wherein the first and second parts are first and second groups of bits representing a single magnitude.

86. The system of claim 85, wherein the magnitude is a magnitude of a single pixel.

87. The system of claim 86, wherein the magnitude is a magnitude of a single color of a single pixel.

88. The system of claim 85, wherein each group of bits contains at least one bit.

89. The system of claim 80, wherein the first and second parts are first and second groups of bits in a header of a video stream, or first and second groups of bits in a motion vector of a video stream, or first and second groups of bits in at least one DCT coefficient in a video stream, or first and second groups of DCT coefficients in at least one group of coefficients in a video stream, or first and second parts of graphics parameters, or first or second parts of spectral transform coefficients, or first and second groups of pixels in a frame, or first or second groups of frames, or first and second groups of bits representing spectral envelope information in an audio stream, or first and second groups of bits representing bandpass scaled signals in an audio stream.

90. The system of claim 80, wherein at least one bit in the first part is more significant than any bit in the second part.
